(19) United States
(12) Patent Application Publication
(10) Pub. No.: US 2016/0293580 A1
(43) Pub. Date: Oct. 6, 2016

(54) SYSTEM IN PACKAGE AND METHOD FOR MANUFACTURING THE SAME

(71) Applicant: NEPES CO., LTD., Chungcheongbuk-do (KR)

(72) Inventors: Jun-Kyu LEE, Chungcheongbuk-do (KR); Yong-Tae KWON, Chungcheongbuk-do (KR)

(73) Assignee: NEPES CO., LTD., Chungcheongbuk-do (KR)

(21) Appl. No.: 14/951,434

(22) Filed: Nov. 24, 2015

(30) Foreign Application Priority Data
Apr. 3, 2015 (KR) 10-2015-0047466

(51) Int. Cl. H01L 25/065; H01L 23/495; H01L 23/528; H01L 25/00; H01L 21/56; H01L 21/311; H01L 23/29; H01L 23/00; H01L 23/31

(52) U.S. Cl. CPC H01L 25/0657; H01L 24/09; H01L 23/49517; H01L 23/528; H01L 23/3171; H01L 24/32; H01L 24/89; H01L 24/03; H01L 24/83; H01L 24/85; H01L 24/27; H01L 21/563; H01L 21/31133; H01L 23/293; H01L 25/50; H01L 2924/0665; H01L 2924/1431; H01L 2224/08245; H01L 2225/0651; H01L 2225/06524; H01L 2224/08145; H01L 2224/32145; H01L 2924/186; H01L 2924/1434

(57) ABSTRACT

Disclosed herein is a system in package and a method of manufacturing the same. The system in package includes a first semiconductor die including a plurality of bond pads, a lead frame disposed around the first semiconductor die and provided with a plurality of signal leads, a second semiconductor die disposed in an upper side of the first semiconductor die and connected to the lead frame by wire bonding, and a fan out metal pattern disposed in a lower side of the first semiconductor die and the lead frame to connect the bond pads and the signal leads electrically and provided with a plurality of metal pads.

### CROSS-REFERENCE TO RELATED APPLICATION

This application claims the benefit of Korean Patent Application No. 2015-047466, filed on Apr. 3, 2015 in the Korean Intellectual Property Office, the disclosure of which is incorporated herein by reference.

### BACKGROUND

1. Field

Embodiments of the present disclosure relate to a system in package and a method of manufacturing the same, more particularly, a wire bonding type system in package in which fan out metal patterns are formed through a simple manufacturing process, and a method of manufacturing the same.

2. Description of the Related Art

In recent years, as for semiconductor components, due to the miniaturization of a processing technology and the diversification of functions, the size of chip is miniaturized and the number of input/output terminal is increased so that an electrode pad pitch is miniaturized more and more. In addition, since the fusion of various functions is accelerated, a system level packaging technology, which is a plurality of elements are integrated in a single package, is on the rise. The system level packaging technology has been changed to be a three dimensional stacking technique, which can keep a short signal length in order to minimize a noise between operations and to improve a signal speed. On the other hand, because of the requirements of the improvement of these techniques, and the high productivity and the reduction of the manufacturing cost to control the rise in product prices, a stacked package that is formed by stacking a plurality of semiconductor chips have been introduced, e.g. Multi Chip Package (MCP) in which a plurality of chips are stacked in a single semiconductor package, and System in Package (SiP) in which stacked heterogeneous chips are operated in a single system.

However, in the semiconductor package manufacturing process using a semiconductor die, bond pads formed with a narrow gap in the semiconductor die may be needed to be more widely expanded to be mounted to an external connection terminal in a large size, e.g. a solder ball and a bump.

To meet these needs, a fan-out semiconductor package capable of effectively expanding the arrangement of the bond pads included in the semiconductor die has been introduced. Meanwhile, the fan-out structure in a semiconductor package, refers to a structure in which the rerouting pattern connected to the bond pads are rearranged to be expanded wider than the size of the semiconductor die and the fan—in structure refers to a structure in which the bond pad is rearranged again in the size range of the semiconductor die.

### RELATED ART DOCUMENT

U.S. published patent No. 2009/261,462 A1.

### SUMMARY

Therefore, it is an aspect of the present disclosure to provide a system in package having a fan-put metal pattern under a semiconductor die, wherein the system in package is operated as a single system by stacking a plurality of dies, and a method of manufacturing the same capable of reducing processing cost by simplifying a manufacturing process.

Additional aspects of the disclosure will be set forth in part in the description which follows and, in part, will be obvious from the description, or may be learned by practice of the disclosure.

In accordance with one aspect of the present disclosure, a system in package includes a first semiconductor die, a lead frame, a second semiconductor die, and a fan out metal pattern. The first semiconductor die may include a plurality of bond pads. The lead frame may be disposed around the first semiconductor die and may include a plurality of signal leads. The second semiconductor die may be disposed in an upper side of the first semiconductor die and may be connected to the lead frame by wire bonding. The fan out metal pattern may be disposed in a lower side of the first semiconductor die and the lead frame to connect the bond pads and the signal leads, electrically and may include a plurality of metal pads.

The system in package may further include an insulation layer disposed in a lower side of the first semiconductor die and the lead frame.

A portion of the insulation layer may be etched to expose the bond pads and the lead frames, and the fan out metal pattern may be disposed in a lower side of the insulation layer to connect the bond pads and the signal leads.

The system in package may further include a bonding layer disposed between the first semiconductor die and the second semiconductor die.

The bonding layer may include an epoxy resin.

The system in package may further include a conductive connection terminal disposed in a lower side of the metal pads to be connected electrically to the fan out metal pattern.

The conductive connection terminal may be a solder ball or a solder bump.

The system in package may further include a sealing layer configured to cover the first semiconductor die, the second semiconductor die, and the lead frame.

The sealing layer may include an epoxy resin.

The first semiconductor die or the second semiconductor die may include a memory chip or a logic chip configured to control the memory chip.

The memory chip may be a dynamic random access memory (DRAM), a static random access memory (SRAM), a flash, a phase change random access memory (PRAM), a resistive random access memory (ReRAM), a ferroelectric random access memory (FeRAM) or a magnetoresistive random access memory (MRAM).

In accordance with another aspect of the present disclosure, a method of manufacturing a system in package includes forming a first semiconductor die including a plurality of bond pads, and a second semiconductor die, which is disposed around the first semiconductor die and provided with a plurality of signal leads, on a base, bonding the second semiconductor die to an upper side of the first semiconductor die, performing wire bonding between the second semiconductor die and the lead frame, separating the base from the first semiconductor die and the lead frame, and forming a fan out metal pattern, which is configured to connect the bond pads and the signal leads electrically and provided with a plurality of metal pads, in a lower side of the first semiconductor die and the lead frame.

A bonding layer may be formed between the first semiconductor die and the second semiconductor die.

The method may further include forming a first insulation layer and exposing the bond pads and the signal leads by etching a portion of the first insulation layer prior to forming the fan out metal pattern.

The method may further include, after forming the fan out metal pattern, forming a second insulation layer configured to cover the fan out metal pattern, exposing the metal pads by etching a portion of the second insulation layer, and forming a conductive connection terminal, which is configured to be electrically connected to the fan out metal pattern, in a lower side of the exposed metal pads.

The method may further include forming a sealing layer configured to cover the first semiconductor die, the second semiconductor die, and the lead frame prior to separating the base from the first semiconductor die and the lead frame.

### BRIEF DESCRIPTION OF THE DRAWINGS

These and/or other aspects of the disclosure will become apparent and more readily appreciated from the following description of the embodiments, taken in conjunction with the accompanying drawings of which:

FIG. 1 is a perspective view illustrating a wire bond type system in package in accordance with a first embodiment of the present disclosure; and

FIGS. 2 to 9 are cross-sectional views illustrating a method of manufacturing the wire bond type system in package of FIG. 1.

### DETAILED DESCRIPTION

Reference will now be made in detail to embodiments of the present disclosure, examples of which are illustrated in the accompanying drawings. Embodiments of the present disclosure are offered to illustrate more fully aspects of the present disclosure to person skilled in the art and the following embodiments may be modified in the form of a range of the aspect of the present disclosure, but is not limited to the following embodiments. Rather, these embodiments are provided to further enhance the present disclosure, and to illustrate completely the aspect of the present disclosure to those skilled in the art. In the drawings, illustration of a part, which is not related to the description may be omitted to clarify the present disclosure, and the size of the component may be slightly illustrated to be exaggerated.

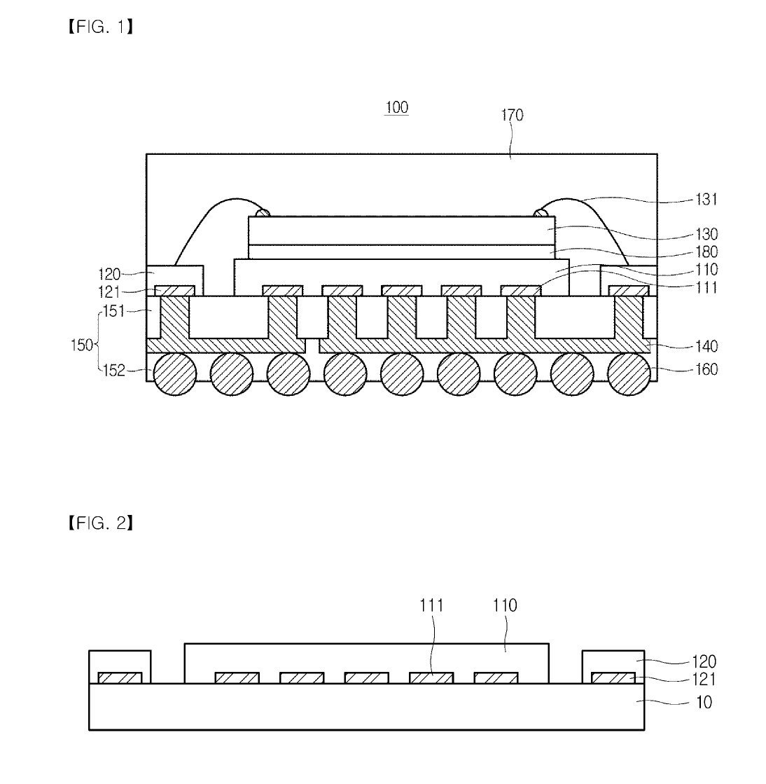

FIG. 1 is a perspective view illustrating a wire bond type system in package in accordance with a first embodiment of the present disclosure.

Referring to FIG. 1, a wire bond type system in package 100 according to an embodiment may include a first semiconductor die 110, a lead frame 120, a second semiconductor die 130, a fan out metal pattern 140, an insulation layer 150, a conductive connection terminal 160, and a sealing layer 170.

The system in package according to an embodiment may be a wire bond type system in package. The wire bond type system in package may have an improved S-parameter (S21) and thus may have the lowest power loss in comparison with another system in package, e.g. package on package type system in package (POP SiP) and face to face type system in package (F2F SiP).

The first semiconductor 110 may include a plurality of bond pads 111.

The lead frame 120 may be disposed around the first semiconductor die 110. The lead frame 120 may include a plurality of signal leads 121.

The second semiconductor die 130 may be disposed in an upper side of the first semiconductor die 110. The second semiconductor die 130 may be connected to the lead frame 120 by wire bonding through a wire 131.

Although not illustrated, a third semiconductor die, and a fourth semiconductor die may be additionally stacked on the second semiconductor die 130. The semiconductor dies on the second semiconductor die 130 may be connected by wire bonding.

A bonding wire 180 disposed between the first semiconductor die 110 and the second semiconductor die 130 may be further included. That is, the first semiconductor die 110 and the second semiconductor die 130 may be bonded to each other through the bonding layer 180.

For example, the bonding layer 180 may include epoxy resin.

For example, the bonding wire 180 in a film type may bond the first semiconductor die 110 to the second semiconductor die 130, and alternatively the second semiconductor die 130 may be bonded to the first semiconductor die 110 by applying the bonding layer 180 in a resin-type to the first semiconductor die 110.

The first semiconductor die 110 or the second semiconductor die 130 may include a memory chip and a logic chip configured to control the memory chip. For example, the memory chip may include a dynamic random access memory (DRAM), a static random access memory (SRAM), a flash, a phase change random access memory (PRAM), a resistive random access memory (ReRAM), a ferroelectric random access memory (FeRAM) or a magnetoresistive random access memory (MRAM).

For example, the first semiconductor die 110 or the second semiconductor die 130 may include diffident type of chips.

The fan out metal pattern 140 may be disposed in a lower side of the first semiconductor die 110 and the lead frame to connect the bond pads and the signal leads 121 eletrically. The fan out metal pattern 140 may include a plurality of metal pads.

The fan out metal pattern 140 may include conductive materials, e.g. metal. For example, the fan out metal pattern 140 may include copper, aluminum and alloys thereof.

The fan out metal pattern 140 may reroute the first semiconductor die 110 and may be electrically connected to the conductive connection terminal 160. Therefore, an input/output terminal of the first semiconductor die 110 may be miniaturized, and the number of the input/output terminals may be increased. The first semiconductor die 110 may be electrically connected to the fan out metal pattern 140 so that the system in package 100 may have a fan-out structure.

The insulation layer 150 may be disposed under the first semiconductor die 110 and the lead frame 120. For example, the insulation layer 150 may include an organic or inorganic insulating material. For example, the insulation layer 150 may include an epoxy resin.

The insulation layer 150 may include a first insulation layer 151 and a second insulation layer 152. The first insulation layer 151 may be disposed under the first semiconductor die 110 and the lead frame 120, and the second insulation layer 152 may be disposed under the first insulation layer 151.

The first insulation layer 151 may be disposed between the first semiconductor die 110 and the lead frame 120 to insulate therebetween.

A portion of the first insulation layer 151 may be etched and thus the bond pads 111 and the signal leads 121 may be exposed. The fan out metal pattern 140 may be disposed under the first insulation layer 151 to electrically connect the bond pads 111 and the signal leads 121.

The second insulation layer 152 may be disposed on the fan out metal pattern 140. A portion of the second insulation layer 152 may be etched and thus the metal pads of the fan out metal pattern 140 may be exposed.

The conductive connection terminal 160 may be disposed under the metal pads, which is an exposed part of the fan out metal pattern 140, and to be connected to the fan out metal pattern 140 electrically. Therefore, the conductive connection terminal 160 may be mounted or connected to an external device so as to transmit an electrical signal from the system in package to the outside.

The conductive connection terminal 160 may include conductive materials, e.g. metal. For example, the fan out metal pattern 140 may include copper, aluminum and alloys thereof.

The conductive connection terminal 160 may be a solder ball or a solder bump.

The sealing layer 170 may cover the first semiconductor die 110, the second semiconductor die 130, and the lead frame 120. That is, the sealing layer 170 may seal the first semiconductor die 110, the second semiconductor die 130, and the lead frame 120 so that the first semiconductor die 110, the second semiconductor die 130 and the lead frame 120 may be not exposed.

For example, the sealing layer 170 may include an organic or inorganic insulating material. For example, the sealing layer 170 may include an epoxy resin.

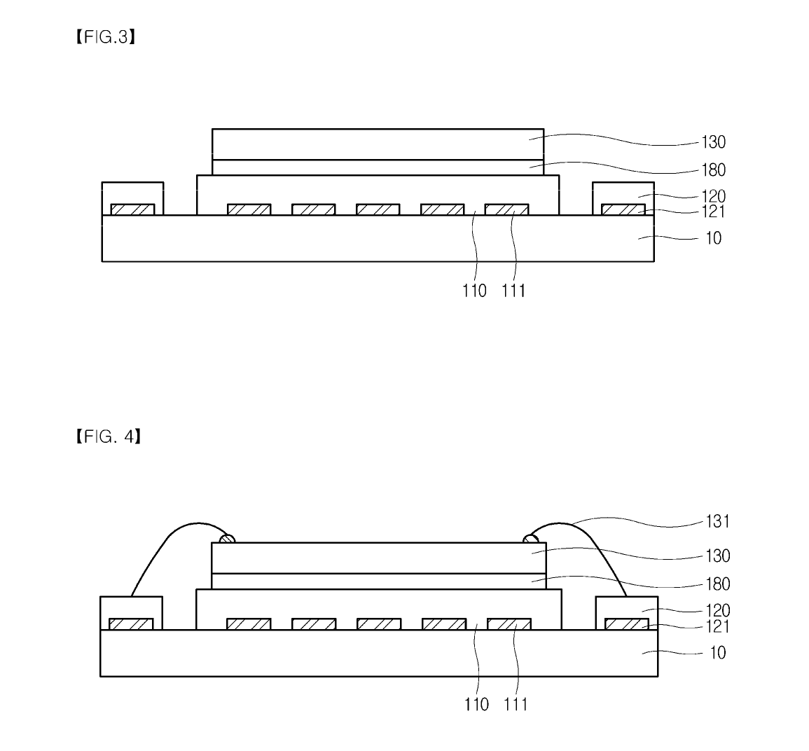

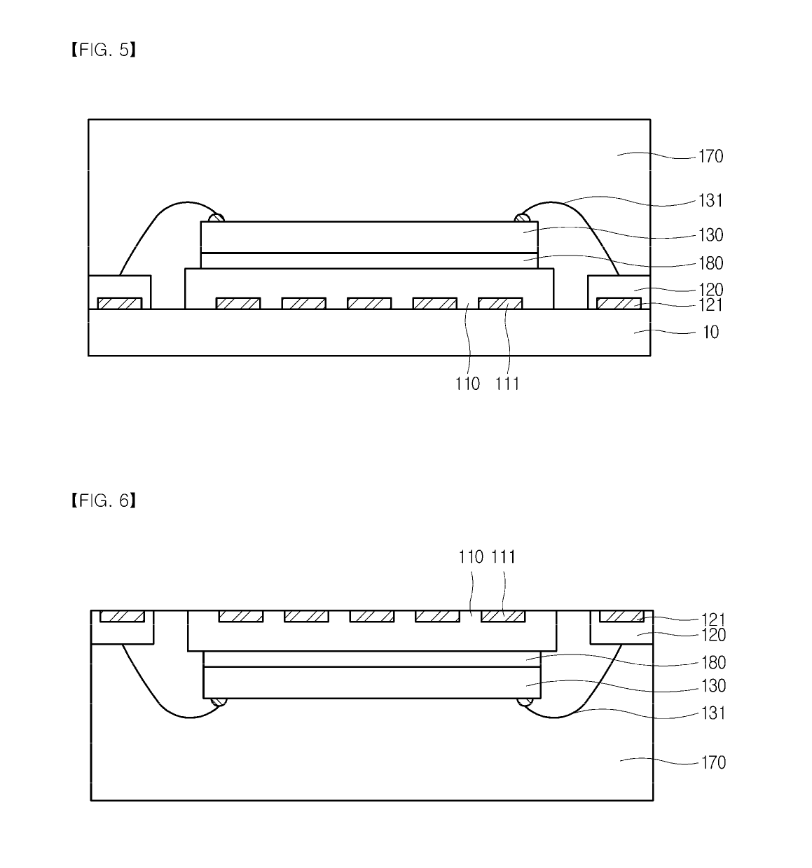

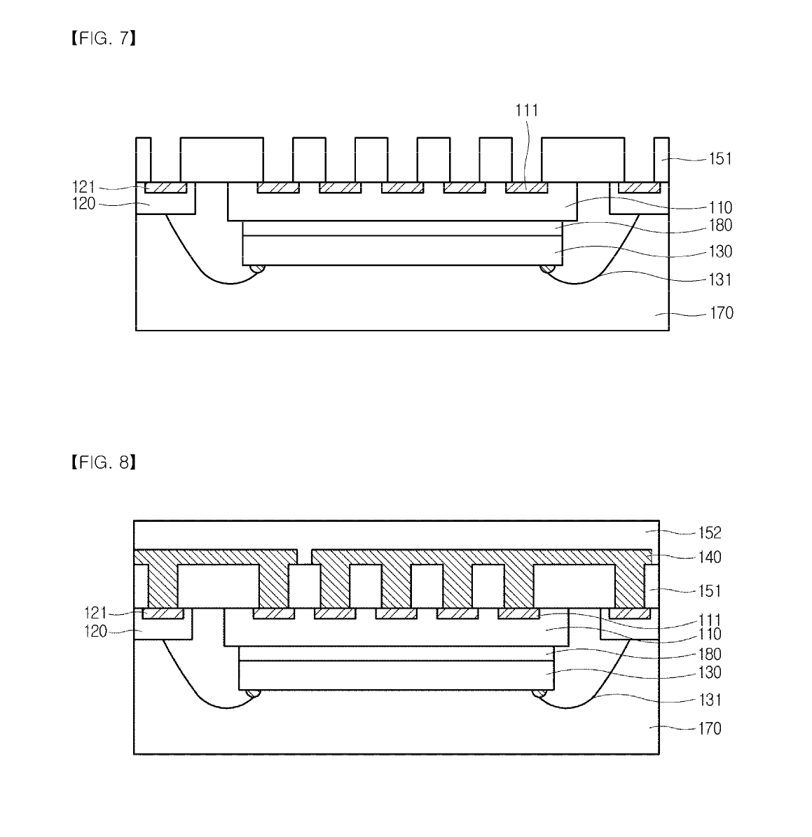

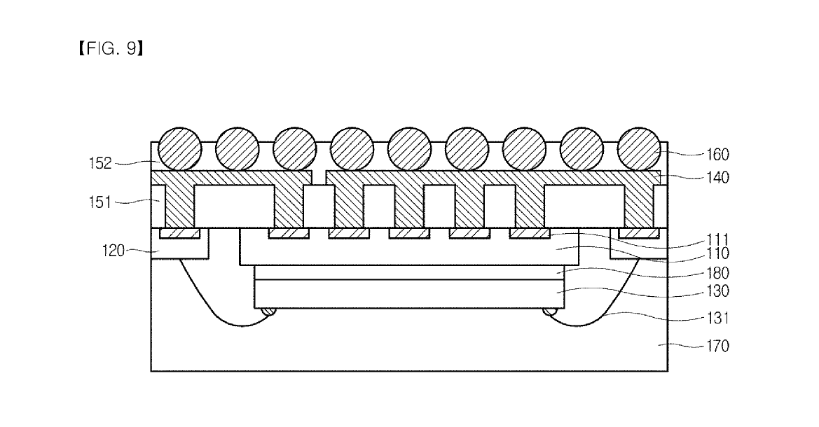

FIGS. 2 to 9 are cross-sectional views illustrating a method of manufacturing the wire bond type system in package of FIG. 1.

Hereinafter a method of manufacturing a wire bond type system in package will be described with reference to FIGS. 1 to 9.

On a base 10, the first semiconductor die 110 including the bond pads and the lead frame 120, which is disposed around the first semiconductor die 110 and includes the plurality of signal leads 121, may be formed.

The base 10 may be used to fix the first semiconductor die 110 and the lead frame 120. After performing an operation in which the second semiconductor die 130 is stacked on the first semiconductor die 110 and the lead frame 120, and connected to the first semiconductor die 110 and the lead frame 120 by wire bonding, and then a sealing process is performed therein, the base 10 may be removed.

The first semiconductor die 110 and the lead frame 120 may be bonded to the base 10 by an adhesive material. For example, after the lead frame 120 is bonded to the base 10, the first semiconductor die 110 may be bonded to the base 10.

The first semiconductor die 110 may include a plurality of bond pads 111. The lead frame 120 may be disposed around the first semiconductor die 110. The lead frame 120 may include a plurality of signal leads 121.

The base 10 may be a rigid type material. For example, mold forming material or polyimide tape may be used as the base 10.

The first semiconductor die 110 may be disposed in a way that a first surface, in which a circuit is formed, is toward the lower side. That is, the first semiconductor die 110 may be disposed to be opposite to an upper surface of the base 10. Therefore, the first semiconductor die 110 may be disposed in a way that a second surface, in which a circuit is not formed, is toward the upper side.

Sequentially, the second semiconductor die 130 may be stacked on the first semiconductor die 110. For example, the second semiconductor die 130 may be bonded above the first semiconductor die 110.

The first semiconductor die 110 or the second semiconductor die 130 may include a memory chip and a logic chip configured to control the memory chip. For example, the memory chip may include a dynamic random access memory (DRAM), a static random access memory (SRAM), a flash, a phase change random access memory (PRAM), a resistive random access memory (ReRAM), a ferroelectric random access memory (FeRAM) or a magnetoresistive random access memory (MRAM).

For example, the first semiconductor die 110 or the second semiconductor die 130 may include diffident type of chips.

A bonding wire 180 disposed between the first semiconductor die 110 and the second semiconductor die 130 may be included. That is, the first semiconductor die 110 and the second semiconductor die 130 may be bonded to each other through the bonding layer 180.

For example, the bonding layer 180 may include epoxy resin.

For example, the bonding wire 180 in a film type may bond the first semiconductor die 110 to the second semiconductor die 130, and alternatively the second semiconductor die 130 may be bonded to the first semiconductor die 110 by applying the bonding layer 180 in a resin-type to the first semiconductor die 110.

The second semiconductor die 130 may be disposed above the first semiconductor die 110. The second semiconductor die 130 may be connected to the lead frame 120 by wire bonding through a wire 131.

After the lead frame 120 and the second semiconductor die 130 are connected to each other by wire bonding, the sealing layer 170 may be formed on the first semiconductor die 110, the second semiconductor die 130 and the lead frame 120.

The sealing layer 170 may cover the first semiconductor die 110, the second semiconductor die 130, and the lead frame 120. That is, the sealing layer 170 may seal the first semiconductor die 110, the second semiconductor die 130, and the lead frame 120 so that the first semiconductor die 110, the second semiconductor die 130, and the lead frame 120 may be not exposed.

For example, the sealing layer 170 may include an insulation material. For example, the sealing layer 170 may include an epoxy resin.

After applying the insulation material to the second semiconductor die 130, the first semiconductor die 110 and the lead frame 120, in which wire bonding is performed, heat curing and light curing may be performed thereon and thus the sealing layer 170 may be formed.

After forming the sealing layer 170, the base 10 may be separated from the first semiconductor die 110 and the lead frame 120.

Although the base 10 is bonded to the first semiconductor die 110 and the lead frame 120 by the adhesion material, the base 10 may be easily separated from the first semiconductor die 110 and the lead frame 120.

After the first semiconductor die 110, the lead frame 120 and the second semiconductor die 130 all of which are fixed by the sealing layer 170 is separated from the base 10 the first semiconductor die 110, the lead frame 120 and the second semiconductor die 130 may be inversed to be upside-down and then a next process may be proceeded.

Hereinafter an arrangement between components will be described while it is assumed that an arrangement between components is an arrangement in a state in which the semiconductor dies are not inversed.

The first insulation layer 151 may be formed under the first semiconductor die 110 and the lead frame 120, which are separated from the base 10.

The first insulation layer 151 may include an organic or inorganic insulating material. For example, the first insulation layer 151 may include an epoxy resin.

The first insulation layer 151 may be formed by applying the insulation material to the lower portion of the first semiconductor die 110 and the lead frame 120. A portion of the first insulation layer 151 may be etched to correspond to an area in which the bond pads 111 and the signal leads 121 are disposed. The first insulation layer 151 may be etched in a dry or wet manner.

Therefore, the portion of the first insulation layer 151 may be etched so that the bond pads 111 and the signal leads 121 may be exposed.

A metal layer may be formed by depositing a metal material to the first insulation layer 151.

The metal material may include conductive materials, e.g. metal. For example, the metal material may include copper, aluminum and alloys thereof.

The fan out metal pattern 140 may be formed by etching the metal layer. The fan out metal pattern 140 may electrically connect the bond pads 111 and the signal leads 121, which are under the first semiconductor die 110 and the lead frame 120, and may include a plurality of metal pads. For example, the metal layer may be easily etched through a photo-resist process so that the fan out metal pattern 140 may be formed.

The fan out metal pattern 140 may reroute the first semiconductor die 110 and may be electrically connected to the conductive connection terminal 160. Therefore, an input/output terminal of the first semiconductor die 110 may be miniaturized, and the number of the input/output terminals may be increased. The first semiconductor die 110 may be electrically connected to the fan out metal pattern 140 so that the system in package 100 may have a fan-out structure.

Therefore the first insulation layer 151 may be disposed between the first semiconductor die 110 and the lead frame 120, and the fan out metal pattern 140 so as to insulate the first semiconductor die 110 and the lead frame 120 from the fan out metal pattern 140.

The second insulation layer 152 may be formed under the fan out metal pattern 140.

The second insulation layer 152 may include organic or inorganic insulating material. For example the second insulation layer 152 may include an epoxy resin.

The second insulation layer 152 may formed by applying the insulation material to a lower portion of the fan out metal pattern 140. A portion of the second insulation layer 152 may be etched to correspond to an area to which the conductive connection terminal 160 is to be connected. The second insulation layer 152 may be etched in a dry or wet manner.

Therefore, a portion of the second insulation layer 152 may be etched so as to expose the metal pads.

The conductive connection terminal 160 may be disposed under the metal pads.

The conductive connection terminal 160 may be disposed under the metal pads, which is an exposed part of the fan out metal pattern 140, and to be connected to the fan out metal pattern 140 electrically. Therefore, the conductive connection terminal 160 may be mounted or connected to an external device so as to transmit an electrical signal from the system in package to the outside.

The conductive connection terminal 160 may include conductive materials, e.g. metal. For example, the conductive connection terminal 160 may include copper, aluminum and alloys thereof.

For example, the conductive connection terminal 160 may be a solder ball or a solder bump.

As is apparent from the above description, according to the proposed system in package, by including fan-out metal pattern under the semiconductor die of wire bond type system in package (WB SiP), bond pads with a narrow gap formed on the semiconductor die may be more widely expanded.

According to the proposed method of manufacturing system in package, by providing a method of manufacturing wire bond type system in package (WB SiP), the number of process may be reduced and processing cost may be reduced in comparison with another system in package, e.g. package on package type system in package (POP SiP) and face to face type system in package (F2F SiP).

Although a few embodiments of the present disclosure have been shown and described, it would be appreciated by those skilled in the art that changes may be made in these embodiments without departing from the principles and spirit of the disclosure, the scope of which is defined in the claims and their equivalents.

What is claimed is:

1. System in package comprising:
a first semiconductor die including a plurality of bond pads;
a lead frame disposed around the first semiconductor die and provided with a plurality of signal leads;
a second semiconductor die disposed in an upper side of the first semiconductor die and connected to the lead frame by wire bonding; and
a fan out metal pattern disposed in a lower side of the first semiconductor die and the lead frame to connect the bond pads and the signal leads electrically and provide with a plurality of metal pads.

2. The system in package of claim 1 further comprising:
an insulation layer disposed in a lower side of the first semiconductor die and the lead frame.

3. The system in package of claim 2, wherein
a portion of the insulation layer is etched to expose the bond pads and the lead frames, and the fan out metal pattern is disposed in a lower side of the insulation layer to connect the bond pads and the signal leads.

4. The system in package of claim 1 further comprising:
a bonding layer disposed between the first semiconductor die and the second semiconductor die.

5. The system in package of claim 4, wherein
the bonding layer comprises an epoxy resin.

6. The system in package of claim 1 further comprising:
a conductive connection terminal disposed in a lower side of the metal pads to be connected electrically to the fan out metal pattern.

7. The system in package of claim 6, wherein
the conductive connection terminal is a solder ball or a solder bump.

8. The system in package of claim 1 further comprising:
a sealing layer configured to cover the first semiconductor die, the second semiconductor die, and the lead frame.

9. The system in package of claim 8, wherein
the sealing layer comprises an epoxy resin.

10. The system in package of claim 1, wherein
the first semiconductor die or the second semiconductor die comprises a memory chip or a logic chip configured to control the memory chip.

11. A method of manufacturing of system in package comprising:
forming a first semiconductor die including a plurality of bond pads, and a lead frame disposed around the first semiconductor die and including a plurality of signal leads, on a base;
attaching a second semiconductor die to an upper side of the first semiconductor die;
performing wire bonding between the second semiconductor die and the lead frame;
separating the base from the first semiconductor die and the lead frame; and
forming a fan out metal pattern, which is configured to electrically connect the bond pads and the signal leads and provided with a plurality of metal pads, at a lower side of the first semiconductor die and the lead frame.

12. The method of claim 11, wherein
a bonding layer is formed between the first semiconductor die and the second semiconductor die.

13. The method of claim 11 further comprising:
forming a first insulation layer prior to forming the fan out metal pattern; and
exposing the bond pads and the signal leads by etching a portion of the first insulation layer.

14. The method of claim 13 further comprising
forming a second insulation layer configured to cover the fan out metal pattern after forming the fan out metal pattern;
exposing the metal pads by etching a portion of the second insulation layer; and
forming a conductive connection terminal, which is electrically connected to the fan out metal pattern, in a lower side of the exposed metal pads.

15. The method of claim 11 further comprising
forming a sealing layer configured to cover the first semiconductor die, the second semiconductor die, and the lead frame prior to separating the base from the first semiconductor die and the lead frame
